(19) United States
(12) Patent Application Publication
(10) Pub. No.: US 2015/0348764 A1
(43) Pub. Date: Dec. 3, 2015

(54) ROTATING DISK CARRIER WITH PBN HEATER

(71) Applicant: WD Media, LLC, San Jose, CA (US)

(72) Inventors: ALLEN J. BOUREZ, SAN JOSE, CA (US); YEW MING CHIONG, SAN JOSE, CA (US)

(73) Assignee: WD Media, LLC, San Jose, CA (US)

(21) Appl. No.: 14/288,157

(22) Filed: May 27, 2014

(51) Int. Cl. H01J 37/32

(52) U.S. Cl. CPC H01J 37/32899

(57) ABSTRACT

Various embodiments provide a substrate carrier configured to rotatably carry at least one substrate through a plurality of processing stations. The substrate carrier includes an integrated heater for heating a first side of the substrate while the second side of the substrate undergoes one or more manufacturing processes at each of the plurality of processing stations, e.g., to promote the desired growth of HAMR media. This can result in the elimination of one or more processing stations, thereby realizing cost savings, decreased substrate processing time, as well as a reduced area within which a substrate processing system can be implemented.

### BACKGROUND

A variety of equipment may be used in the manufacture of disk drive/magnetic recording media to form different magnetic and non-magnetic layers. In a typical process, a glass or aluminum substrate travels sequentially through a number of processing stations at which different materials are deposited onto the substrate under different conditions. For example, one or more sputtering systems may be used to sputter magnetic and/or non-magnetic materials onto the substrate. Sputtering can refer to a process by which a substrate is coated with desired materials using ion bombardment of a target material. A voltage potential is applied to a target to accelerate ions and bombard the target surface. As a result, target material will dislodge at an atomic level and sputter and deposit to the substrate.

In conventional sputtering processes, active sputtering stations for disk drive media are separated by finite distances. Without such separation, electromagnetic interference might occur between the sputtering stations and result in inhomogeneous sputtering or even equipment failure. Thus, the sputtering stations are physically separated, or, if closely situated, the sputtering stations may not be not used concurrently. Indeed, in some sputtering systems, sputtering components may be shared between adjacent sputtering stations and may be moved back and forth between them as the active sputtering station changes.

For many types of substrates, magnetic recording media has begun to incorporate perpendicular magnetic recording (PMR) technology in an effort to increase areal density. Generally, PMR media may be partitioned into two primary functional regions: a soft underlayer (SUL) and a magnetic recording layer(s) (RL). With the advent of heat-assisted magnetic recording (HAMR) media, areal density in hard disk drives can be extended beyond 1 Tb/in². However, superparamagnetic limits, thermal stability, and writability issues can limit the ability to increase areal densities in hard disk drives using conventional PMR media. Thus, and in order to support higher areal densities while also providing thermal stability, HAMR media is often made of magnetic materials or compounds with substantially higher magnetocrystalline anisotropy (indicated by the magnetic anisotropy constant, Kᵤ) than that of non-HAMR media (e.g., Cobalt-Chromium-Platinum (CoCrPt) alloys). One example of such an alloy having substantially higher magnetocrystalline anisotropy is the L1₀ phase of Iron-Platinum (FePt) alloys. In principle, the higher Kᵤ of L1₀ FePt allows grains as small as 2-5 nm to remain thermally stable. Unlike CoCrPt alloys however, growth of chemically ordered L1₀ FePt requires a deposition temperature greater than 500° C.

### BRIEF DESCRIPTION OF THE DRAWINGS

Various embodiments are illustrated by way of example, and not limitation, in the figures of the accompanying drawings in which:

FIG. 1 illustrates an example disk processing system in which a rotating disk carrier having a Pyrolytic Boron Nitride (PBN) heater can be implemented in accordance with various embodiments;

FIG. 2 illustrates a front perspective view of an example rotating disk carrier in accordance with various embodiments;

FIG. 3 illustrates a rear perspective view of the rotating disk carrier of FIG. 2;

FIG. 4 illustrates a cross-section view of the rotating disk carrier of FIG. 2;

FIG. 5 illustrates another front perspective view of two example rotating disk carriers in accordance with various embodiments; and

FIG. 6 illustrates an example disk drive in which a disk generated utilizing a rotating disk carrier in accordance with various embodiments can be utilized.

### DETAILED DESCRIPTION

In the following description, numerous specific details are set forth, such as examples of specific layer compositions and properties, to provide a thorough understanding of various embodiment of the present invention. It will be apparent however, to one skilled in the art that these specific details need not be employed to practice various embodiments of the present invention. In other instances, well known components or methods have not been described in detail to avoid unnecessarily obscuring various embodiments of the present invention.

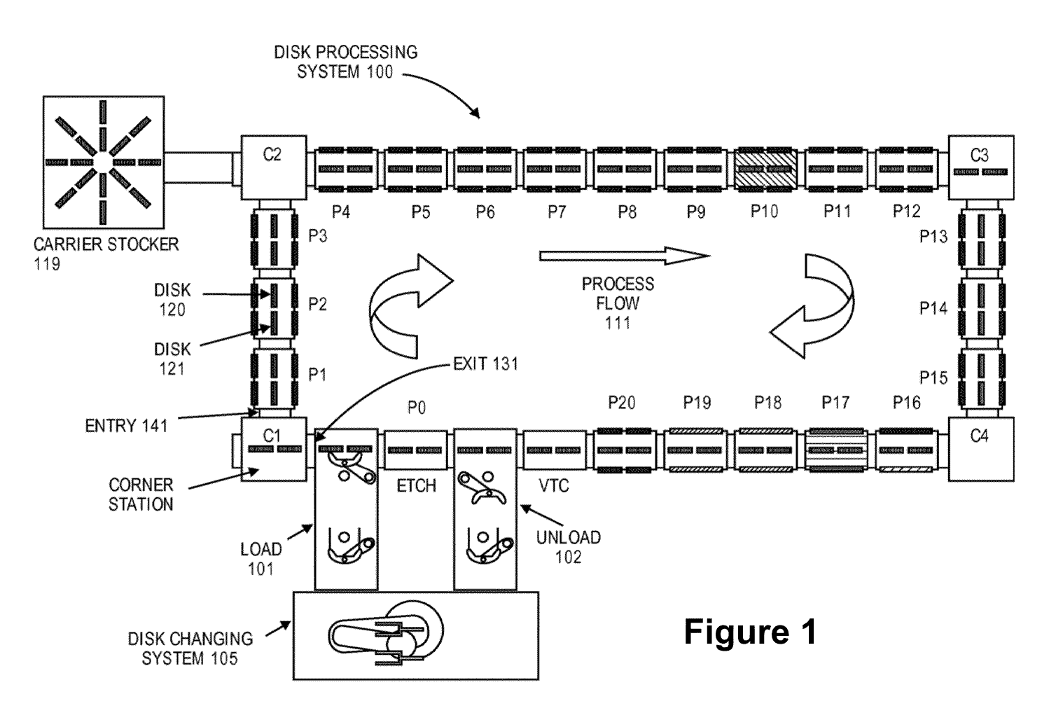

FIG. 1 illustrates an example disk processing system 100 in which a rotating disk carrier having a Pyrolytic Boron Nitride (PBN) heater can be implemented in accordance with various embodiments. Disk processing system 100 may include a plurality of processing chambers situated in different linear sections. Various types of processing chambers may be situated at any of the stations, for example, but not limited to sputter, chemical vapor deposition (CVD), etching, cooling, heating, load, unload, etch, etc. The disk processing system 100 illustrated in FIG. 1 includes process stations P1-P20, corner stations C1-C4, an etch chamber P0, a load chamber 101 and an unload chamber 102. Process stations P1-P3 are located in a first linear section. Process stations P4-P12 are in a second linear section that is perpendicular to the first linear section. Process stations P13-P15 are in a third linear section that is perpendicular to the second linear section. Process stations P16-P20 are in a fourth linear section that is perpendicular to the third linear section. A disk changing system 105 can be used to transport disks into and out of the disk processing system 100.

A disk transport system transports one or more disks (e.g., disk 120) on disk carriers (stocked in carrier stocker 119) in a process flow 111 among the various stations, e.g., for alloy mixing, substrate biasing, and multi-layer sputtering, as described below. In one embodiment, each disk carrier holds two disks (e.g., disk 120 and 121) such that two disks are processed within a particular station. Alternatively, a disk carrier may secure more or less than two disks.

In one embodiment, disk processing system 100 is a disk sputtering system, where the disk carriers utilized have PBN heaters incorporated therein. In alternative embodiments, the disk processing system 100 may be another type of sputtering system or disk processing system.

Different processing stations P1-P20 are used in various stages of hard drive manufacture in the conventional manner. For example, a first set of the processing stations may be used to deposit one or more sub-layers of a soft magnetic layer for a PMR medium. A second set of processing stations may be used to deposit other intermediate layers, such as a second soft magnetic layer. A further set of processing stations may be used to deposit the hard magnetic layer on the PMR medium. After the hard magnetic layer is deposited, one or more of the processing stations is used for cooling. After cooling, the disk carrier may enter a final set of processing stations for application of overcoats, including a carbon coat. It should be noted that one or more of the chambers may be unused or may serve as standby stations during processing.

The corner stations C1-C4 operate to connect the differently oriented liner sections of the processing system. More specifically, corner stations C1-C4 may connect a prior station whose exit is at an angle (e.g., perpendicular) with respect to the entry of a subsequent station within process flow 111. For example, exit 131 of load station 101 is perpendicularly oriented with respect to entry 141 of station P1. Corner station C1 can include a rotation assembly that re-orients a disk carrier received in one direction from load chamber 101 to a perpendicular direction for transport into station P1.

In alternative embodiments, disk processing system 100 may have more or less than the number of stations/chambers illustrated in FIG. 1. That is, incorporation of a heater, such as a PBN heater, into a disk carrier itself in accordance with various embodiments, allows for the elimination of one or preferably more stations/chambers in a conventional disk processing system, such as disk processing system 100. For example, a disk processing system in which a heater-integrated disk carrier is used may result in only five process chambers for alloy mixing and sputtering, which can include the following: Al granule seed layer sputtering; full size Magnesium Oxide (MgO) target sputtering; alloy mixing where Silicon Dioxide (SiO₂), Cu, Al, Ag, etc. targets are utilized to make a grain isolation layer; Fe, Pt, Cr, or SiO₂ target sputtering; and the deposition of a protective carbon overcoat, e.g., a diamond-like carbon (DLC) coating.

Conventional disk processing systems may utilize one or more heating elements that are stationary, i.e., integrated into/as part of a particular station or chamber. In contrast, a disk carrier in accordance with various embodiments utilizes a heater integrated into/as part of the disk carrier itself, such that the heater can move with the disk/disk carrier. As opposed to conventional disk processing systems, where a disk/disk carrier would be passed along to a specific heating station/chamber in order to allow the disk to be heated, a disk carried in a disk carrier can be heated, for example, at will, in accordance with various embodiments. The elimination of one or more processing stations/chambers can result in cost savings, decreased disk processing time, as well as a reduced area within which a disk processing system can be implemented, which in turn can result in the consumption of fewer resources.

As alluded to previously, L1₀ ordered FePt is an example of an alloy that can be used in HAMR applications, where a high temperature process may be used to obtain the FePt layer with the desired texture and magnetic properties. Chemically ordered L1₀ FePt may be achieved by film deposition on a substrate at high temperatures, e.g., greater than 500° C., or by subjecting substrate to a high temperature post-annealing process after film deposition. It should be noted that in some embodiments, high temperature film deposition can occur at a temperature range between 500° C.-650° C. According, and as will be described in greater detail below, disk carriers may have an integrated heater incorporated therein to heat the backside of a disk during one or more sputtering processes to promote the desired growth of HAMR media. Additionally, and with a temperature control heating system (e.g., temperature controller/processor for controlling, e.g., when the heater is active or not and/or at what temperature the heater is to heat the disk/substrate) also incorporated in the disk carriers, the effects of temperature on sputtered thin film can be ascertained, leading to a better understanding of the effect of temperature on film growth. Although heaters incorporated in a disk carrier in accordance with embodiments disclosed herein are described as being PBN heaters, other embodiments contemplate the utilization of other types of heaters, including but not limited to Calrod® heaters, quartz heaters, etc.

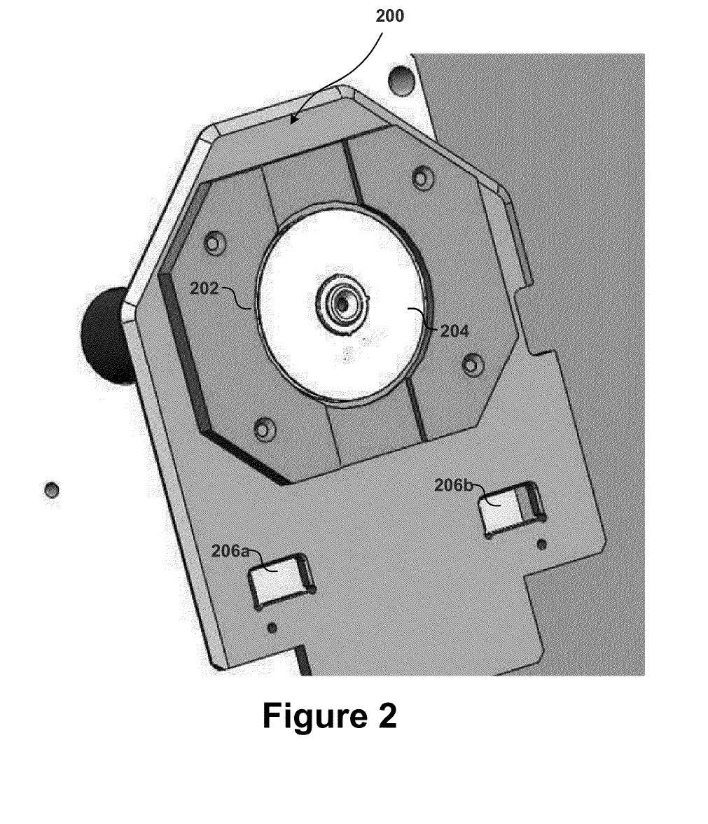

FIG. 2 illustrates a front perspective view of an example disk carrier 200 in accordance with various embodiments, where disk carrier 200 may be one or more of the disk carriers stocked in carrier stocker 119 of disk processing system 100. Disk carrier 200 may include a receptacle 202 for receiving a disk 204 which can rest atop/in front of a PBN heater (not shown in FIG. 2). That is, the PBN heater can be disposed proximate to or along a first side of the disk opposite a second side of the disk undergoing sputtering. In some embodiments, a protective plate may be disposed between disk 204 and the PBN heater, such as a 2 mm quartz plate (not shown). The quartz plate may act as a cover or protective barrier preventing sputtered materials intended for a disk from attaching to the PBN heater. Thus, and in accordance with one embodiment, a disk such as disk 204 may be separated from a quartz plate by, e.g., 1 mm, and the quartz plate may be separated from the PBN heater by, e.g., 0.5 mm. In accordance with another embodiment, disk 204 may be held or otherwise positioned in receptacle 202 such that it rests above/in front of the PBN heater. In either embodiment, the very close proximity of disk 204 to the PBN heater allows for good heating control of the disk 204.

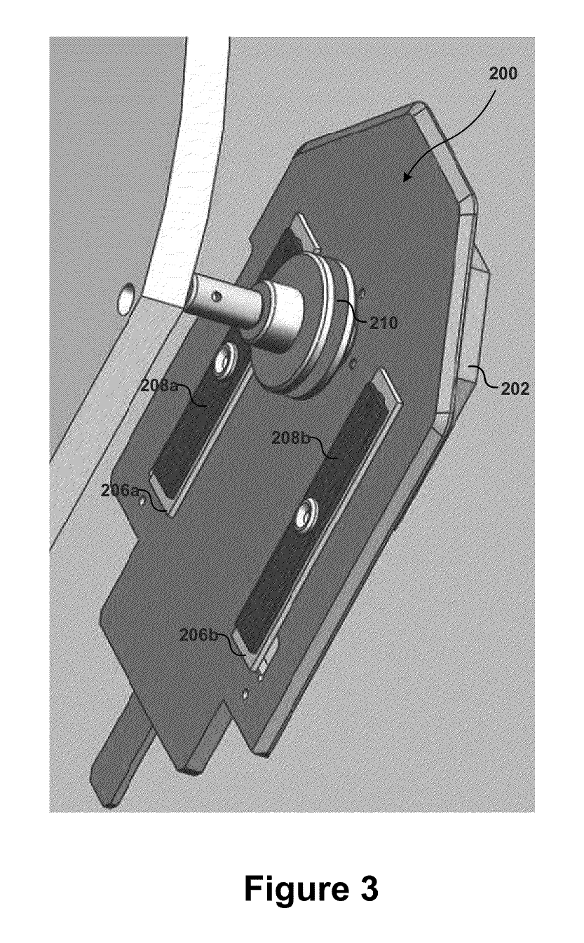

The spinning of disk 204 during, e.g., alloy mixing, or multi-layer sputtering, provides for improved alloy mixing uniformity, as well as multi-layer sputtering. That is, HAMR media material design and/or stacks may rely on ordered alloy deposition, where multiple sputter devices (guns) may be used to make the alloys. In order to achieve growth uniformity, the disk/substrate may be spun in front of a cathode setup, and the integration of a PBN heater with disk carrier 200 allows for this. As will be described in conjunction with FIG. 3, disk carrier 200 may also include electrical insulators 206a and 206b.

As alluded to above, another manufacturing process for which various embodiments may be utilized is substrate biasing during heating or processing. In substrate biasing, disk or substrate 204 can be grounded or floating in disk carrier 200. Positive or negative voltage, e.g., direct current (DC) voltage, may be applied to disk or substrate 204. During the application of the positive or negative DC voltage, the PBN heater can be active (i.e., operatively heating disk or substrate 204) or inactive (i.e., “turned off” and not heating disk or substrate 204).

FIG. 3 illustrates a rear perspective view of disk carrier 200. On a rear portion of disk carrier 200, disk carrier 200 may further include electrical contacts 208a and 208b for driving the PBN heater (not shown in FIG. 3). For example, power supply contacts may meet with electrical contacts 208a and 208b which can then receive power (from a power supply) for operating the PBN heater. It should be noted that electrical contacts 208a and 208b can be retracted in order to control when the PBN heater is active/heating disk 202. For example, utilizing retractable electrical contacts 208a and 208b allows for selectively heating in, e.g., any of the aforementioned five process chambers of a disk processing system. To electrically insulate electrical contacts 208a and 208b from contacting other parts/portions/aspects of disk carrier 200 (e.g., one or more surfaces of disk carrier 200), electrical insulators 206a and 206b are utilized, which may be a ceramic material, such as Alumina (Al₂O₃). Accordingly, electrical contracts 208a and 208b only provide power to the PBN heater. Additionally, disk carrier 200 may include a magnetic drive coupling which facilitates rotation of disk 202. It should be noted that in order to withstand the temperatures generated by the PBN heater, the magnetic drive coupling may be shielded utilizing, e.g., two magnets, such as a neodymium Iron Boron magnet and an Alumina magnet.

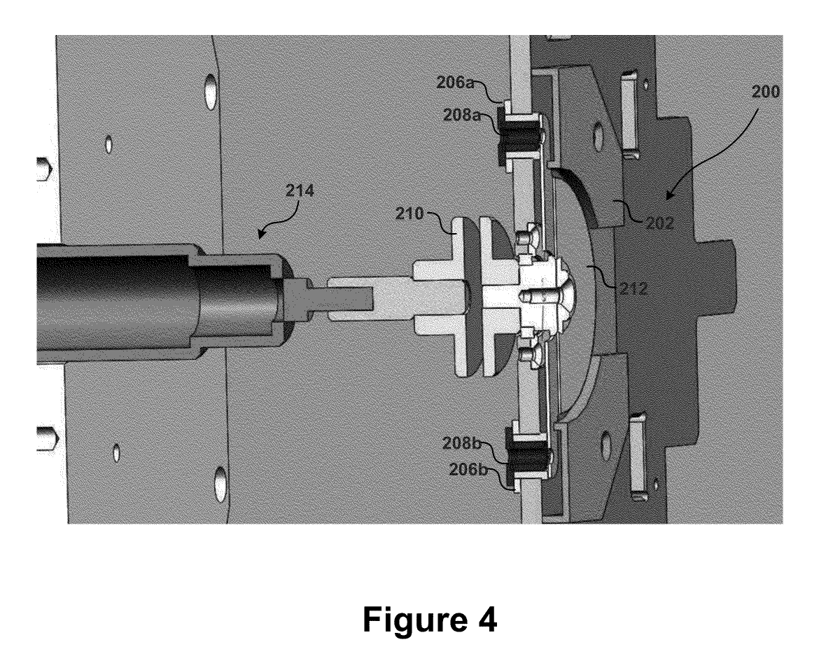

FIG. 4 illustrates a cross-sectional view of disk carrier 200. As illustrated in FIG. 4, disk carrier 200 may include disk receptacle 202 in which a disk 204 may be received for alloy mixing and multi-layer sputtering. Disk receptacle 202 may further provide an area for incorporating PBN heater 212, where disk 202 can rest above PBN heater 212. Also illustrated in FIG. 4 are retractable electrical contacts 208a and 208b for driving PBN heater 212, electrical insulators 206a and 206b, as well as magnetic drive coupling 210 connected to rotating shaft 214. Again, it should be noted that in some embodiments, a protective plate such as a quartz plate (not shown) may be added to disk carrier 200 to act as a cover or protective barrier preventing sputtered materials intended for a disk from attaching to PBN heater 212. Thus, and in accordance with one embodiment, a disk may be separated from the quartz plate by, e.g., 1 mm, and the quartz plate may be separated from PBN heater 212 by, e.g., 0.5 mm.

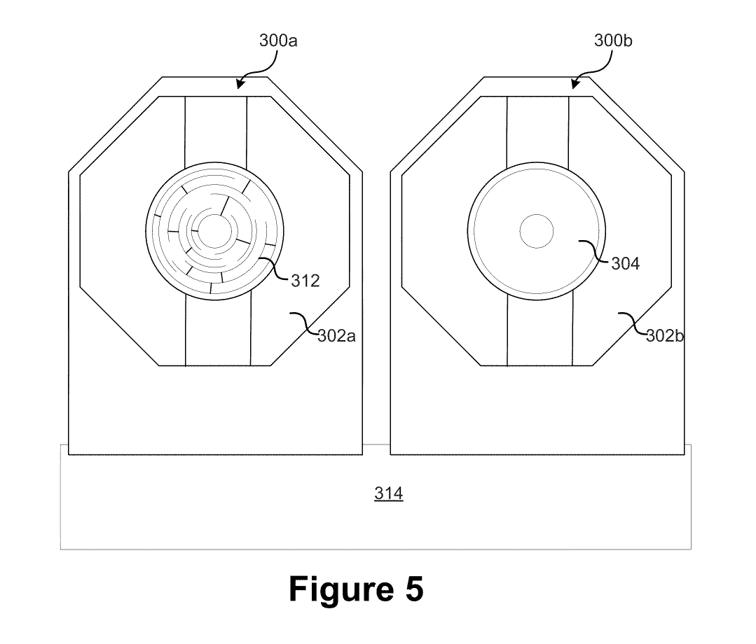

In various embodiments, a disk or substrate carrier assembly may comprise, in part, a transfer rail. As illustrated in FIG. 5, a transfer rail mount 314 allows one or more disk carriers (in this example two disk carriers 300a and 300b) to be transported from station/chamber to station/chamber of the disk processing system. Disk carrier 300a and 300b may be removably mounted to transfer rail mount 314. Disk carriers 300a and 300b each hold a disk during transport through the disk processing system. FIG. 5 illustrates disk carrier 300a without a disk in receptacle 302a in order to show heater 312, while disk carrier 300b is illustrated with a disk 304 in receptacle 302b. As can be appreciated, disk carriers 300a and 300b, each with a heater integrated therein can move throughout the disk processing system, heating a disk as desired.

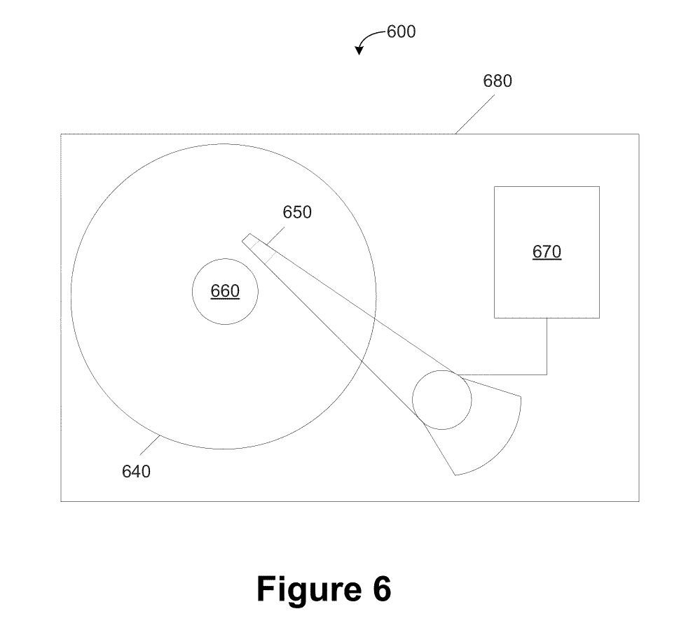

FIG. 6 illustrates a disk drive 600 having one or more disks 640. Disk 640 resides on a spindle assembly 660 that is mounted to drive housing 680. Data may be stored along tracks in the magnetic recording layer of disk 640. The reading and writing of data is accomplished with head 650 that has both read and write elements. The write element is used to alter the properties of the perpendicular magnetic recording layer of disk 640. In one embodiment, head 650 may have magneto-resistive (MR), or giant magneto-resistive (GMR) elements. In an alternative embodiment, head 650 may be another type of head, for example, an inductive read/write head or a Hall effect head. In some embodiments, disk 640 is a HAMR medium, and disk drive 600 is a HAMR drive and incorporate components of a laser source, a waveguide, and a near-field transducer (not shown). Techniques in generating and focusing a laser beam are known in the art, and thus, are not described in particular detail. A spindle motor (not shown) rotates spindle assembly 660 and, thereby, disk 640 to position head 650 at a particular location along a desired disk track. The position of head 650 relative to disk 640 may be controlled by position control circuitry 670.

It should be note that although various embodiments have been described in the context of processing “disks,” other contemplated embodiments may be utilized to accommodate any type of substrate, wafer, or other material. Further still, various embodiments may be utilized to manufacture/process one or more portions of a substrate mounted or otherwise attached to a disk being carried in a disk or substrate carrier for processing. It should be further noted that the shape of a substrate, wafer, or other material can be substantially circular, e.g., a disk shape, or other shapes that can be accommodated in a disk or substrate carrier as described herein. For example, a substrate or wafer can be square-shaped so long as it can fit within, e.g., a receptacle, such as receptacle 302a and 302b of FIG. 5. Additionally, and in alternative embodiments, the receptacle itself need not be necessarily circularly shaped.

Although described above in terms of various exemplary embodiments and implementations, it should be understood that the various features, aspects and functionality described in one or more of the individual embodiments are not limited in their applicability to the particular embodiment with which they are described, but instead can be applied, alone or in various combinations, to one or more of the other embodiments of the application, whether or not such embodiments are described and whether or not such features are presented as being a part of a described embodiment. Thus, the breadth and scope of the present application should not be limited by any of the above-described exemplary embodiments.

The terms “over,” “under,” “between,” and “on” as used herein refer to a relative position of one media layer with respect to other layers. As such, for example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in contact with that second layer. Additionally, the relative position of one layer with respect to other layers is provided assuming operations are performed relative to a substrate without consideration of the absolute orientation of the substrate.

Terms and phrases used in this document, and variations thereof, unless otherwise expressly stated, should be construed as open ended as opposed to limiting. As examples of the foregoing: the term “including” should be read as meaning “including, without limitation” or the like; the term “example” is used to provide exemplary instances of the item in discussion, not an exhaustive or limiting list thereof; the terms “a” or “an” should be read as meaning “at least one,” “one or more” or the like; and adjectives such as “conventional,” “traditional,” “normal,” “standard,” “known” and terms of similar meaning should not be construed as limiting the item described to a given time period or to an item available as of a given time, but instead should be read to encompass conventional, traditional, normal, or standard technologies that may be available or known now or at any time in the future. Likewise, where this document refers to technologies that would be apparent or known to one of ordinary skill in the art, such technologies encompass those apparent or known to the skilled artisan now or at any time in the future.

The presence of broadening words and phrases such as “one or more,” “at least,” “but not limited to” or other like phrases in some instances shall not be read to mean that the narrower case is intended or required in instances where such broadening phrases may be absent. The use of the term “module” does not imply that the components or functionality described or claimed as part of the module are all configured in a common package. Indeed, any or all of the various components of a module, whether control logic or other components, can be combined in a single package or separately maintained and can further be distributed in multiple groupings or packages or across multiple locations.

Additionally, the various embodiments set forth herein are described in terms of exemplary block diagrams, flow charts and other illustrations. As will become apparent to one of ordinary skill in the art after reading this document, the illustrated embodiments and their various alternatives can be implemented without confinement to the illustrated examples. For example, block diagrams and their accompanying description should not be construed as mandating a particular architecture or configuration.

What is claimed is:

1. A disk carrier, comprising:
a receptacle for rotatably carrying a disk through at least one processing station;
a heater integrated into the disk carrier and disposed proximate to a first side of the disk for heating the disk while the disk is rotating in the receptacle and undergoing at least one manufacturing process in the at least one processing station; and
a controller for controlling operation of the heater.

2. The disk carrier of claim 1, wherein the at least one manufacturing process comprises a sputtering process.

3. The disk carrier of claim 2, further comprising a protective plate disposed between the disk and the heater, the protective plate comprising a quartz plate configured to substantially cover the heater from receiving sputtered material resulting from the sputtering process.

4. The disk carrier of claim 1, wherein the at least one manufacturing process comprises one of a multi-layer sputtering process, an alloy mixing process, or a biasing process, the biasing process comprising applying one of a positive direct current (DC) voltage or a negative DC voltage to the disk while the disk is either grounded or floating in the disk carrier, and while the heater is either active or inactive.

5. The disk carrier of claim 1, wherein the rotating of the disk occurs in front of a cathode setup.

6. The disk carrier of claim 1, further comprising a plurality of electrical contacts connecting the heater to the controller and a plurality of power supply contacts for powering the heater.

7. The disk carrier of claim 6, wherein the plurality of electrical contacts are retractable to effectuate selective heating of the disk.

8. The disk carrier of claim 6, further comprising a plurality of electrical insulators configured to insulate the plurality of electrical contacts from contacting at least one surface of the disk carrier, wherein each of the plurality of electrical insulators is composed of a ceramic material.

9. The disk carrier of claim 1, wherein the heater comprises a Pyrolytic Boron Nitride (PBN) heater.

10. The disk carrier of claim 1, wherein the receptacle comprises a magnetic drive coupling for effectuating the rotating of the disk.

11. A processing system, comprising:
a plurality of processing stations; and
at least one substrate carrier configured to rotatably carry at least one substrate through the plurality of processing stations, the at least one substrate carrier comprising an integrated heater for heating a first side of the at least one substrate, wherein the first side is opposite a second side of the at least one substrate that is undergoing a manufacturing process at each of the plurality of processing stations.

12. The processing system of claim 11, further comprising, a transfer rail mount upon which the at least one substrate carrier is mounted, the transfer rail mount allowing the at least one substrate carrier to be transported to and from the plurality of processing stations.

13. The processing system of claim 11, wherein the substrate comprises a heat-assisted magnetic recording (HAMR) media substrate.

14. The processing system of claim 11, wherein the substrate comprises a wafer material.

15. The processing system of claim 11, wherein the substrate carrier is further configured to carry at least one disk upon which one or more substrate portions are mounted.

16. A substrate carrier assembly, comprising:
a mount; and
at least one substrate carrier removably attached to the mount, the at least one substrate carrier configured to rotatably carry a substrate through a plurality of processing stations, the at least one substrate carrier comprising:
an integrated heater disposed along a first side of the substrate for heating the substrate opposite a second side of the substrate that is undergoing at least one manufacturing process in each of the plurality of processing stations;
a plurality electrical contacts for providing power to the integrated heater; and
a magnetic coupling drive for rotating the substrate during the at least one manufacturing process.

17. The substrate carrier assembly of claim 16, further comprising a protective plate disposed between the integrated heater and the substrate for preventing deposition of sputtered material resulting from the at least one manufacturing process on the integrated heater.

18. The substrate carrier assembly of claim 16, wherein the integrated heater comprises a Pyrolytic Boron Nitride (PBN) heater.

19. The substrate carrier assembly of claim 16, wherein the at least one manufacturing process comprises at least one of a multi-layer sputtering process, a substrate biasing process, and an alloy mixing process.

20. The substrate carrier assembly of claim 16, wherein the substrate comprises one or more substrate portions mounted onto a disk.
